(19) United States
(12) Patent Application Publication
(10) Pub. No.: US 2024/0160810 A1
(43) Pub. Date: May 16, 2024

(54) INFORMATION PROCESSING SYSTEM, INFORMATION PROCESSING METHOD, AND PROGRAM

(71) Applicant: NEC Corporation, Tokyo (JP)

(72) Inventor: Hiroshi YOSHIDA, Tokyo (JP)

(73) Assignee: NEC Corporation, Tokyo (JP)

(21) Appl. No.: 18/383,127

(22) Filed: Oct. 24, 2023

(30) Foreign Application Priority Data
Nov. 4, 2022 (JP) 2022-177191

(51) Int. Cl. G06F 30/25

(52) U.S. Cl. CPC G06F 30/25

(57) ABSTRACT

An information processing system 100 according to the present disclosure is an information processing system that forms a plurality of particle filters for estimating states of a plurality of systems. The information processing system includes a determination unit 121 configured to determine a risk of the state of each of the systems based on the state of each of the systems, and a calculation unit 122 configured to calculate the number of particles to be allocated to each of the systems based on the risk and also calculate the number of particles so as to allocate at least a preset minimum number of particles to all the systems.

### CROSS-REFERENCE TO RELATED APPLICATIONS

This application is based upon and claims the benefit of priority from Japanese Patent Application No. 2022-177191 filed in Japan on Nov. 4, 2022, the disclosure of which is incorporated herein in its entirety by reference.

### TECHNICAL FIELD

The present disclosure relates to an information processing system, an information processing method, and a program.

### BACKGROUND ART

A large-scale system like a digital twin includes a large number of independent systems, and causes a demand desiring to simulate the states of these multiple systems in parallel in real-time. Then, one method employed to estimate the states of the multiple systems is to use a particle filter. For example, in Patent Literature 1, a plurality of parts of each person is tracked using the particle filter when a person in a captured image is tracked.

More specifically, in Patent Literature 1, a particle group is allocated to each part of the person, and the position of each part of the person is estimated based on the estimated position and the likelihood of each particle. Then, in Patent Literature 1, the number of particles is set and allocated according to the tracking reliability of the part. Especially, in Patent Literature 1, the number of particles is set so as to reduce the allocation to a part difficult to track and increase the allocation to a highly likely tractable part. The technique of the particle filter is discussed in Patent Literature 2.

### CITATION LIST

### Patent Literature

[Patent Literature 1] Japanese Patent Application Laid-Open No. 2016-170603

[Patent Literature 2] Japanese Patent Application Laid-Open No. 2011-197964

### SUMMARY OF INVENTION

### Technical Problem

However, in the technique discussed in above-described Patent Literature 1, the allocation of particles to the part difficult to track is reduced, which may make estimation with respect to all of the parts difficult. This raises such a problem that, even when the technique discussed in Patent Literature 1 is applied to such a large-scale system that the plurality of systems is included therein, the stability and the accuracy of estimation with respect to the plurality of systems cannot be improved.

In light thereof, an object of the present disclosure is to provide an information processing system capable of solving an inability to improve the stability and the accuracy of estimation with respect to a plurality of systems, which is the above-described problem.

### Solution to Problem

An information processing system according to one aspect of the present disclosure is configured to form a plurality of particle filters for estimating states of a plurality of systems. The information processing system includes:
a determination unit configured to determine a risk of the state of each of the systems based on the state of each of the systems; and
a calculation unit configured to calculate the number of particles to be allocated to each of the systems based on the risk and also calculate the number of particles so as to allocate at least a preset minimum number of particles to all the systems.

Further, an information processing method according to one aspect of the present disclosure is an information processing method for forming a plurality of particle filters for estimating states of a plurality of systems. The information processing method includes:
determining a risk of the state of each of the systems based on the state of each of the systems; and
calculating the number of particles to be allocated to each of the systems based on the risk and also calculating the number of particles so as to allocate at least a preset minimum number of particles to all the systems.

Further, a program according to one aspect of the present disclosure is a program comprising instructions for causing a computer to execute processing for forming a plurality of particle filters for estimating states of a plurality of systems. The processing includes:
determining a risk of the state of each of the systems based on the state of each of the systems; and
calculating the number of particles to be allocated to each of the systems based on the risk and also calculating the number of particles so as to allocate at least a preset minimum number of particles to all the systems.

### Advantageous Effects of Invention

By being configured in this manner, the present disclosure can improve the stability and the accuracy of the estimation with respect to the plurality of systems.

### BRIEF DESCRIPTION OF DRAWINGS

FIG. 1 is a block diagram illustrating the overall configuration of an estimation system according to a first exemplary embodiment of the present disclosure.

FIG. 2 is a block diagram illustrating another configuration of the estimation system disclosed in FIG. 1.

FIG. 3 is a diagram illustrating one example of processing for allocating particles by the estimation system disclosed in FIG. 1.

FIG. 4 is a flowchart illustrating an operation of the estimation system disclosed in FIG. 1.

FIG. 5 is a diagram illustrating an example of use of the estimation system disclosed in FIG. 1.

FIG. 6 is a block diagram illustrating the hardware configuration of an information processing system according to a second exemplary embodiment of the present disclosure.

FIG. 7 is a block diagram illustrating the configuration of the information processing system according to the second exemplary embodiment of the present disclosure.

### DESCRIPTION OF EMBODIMENTS

### First Exemplary Embodiment

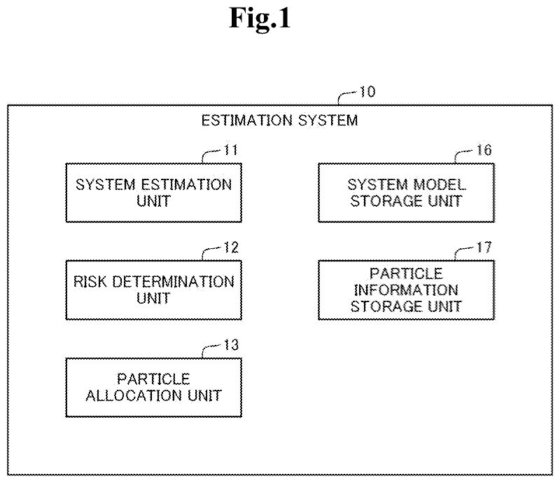

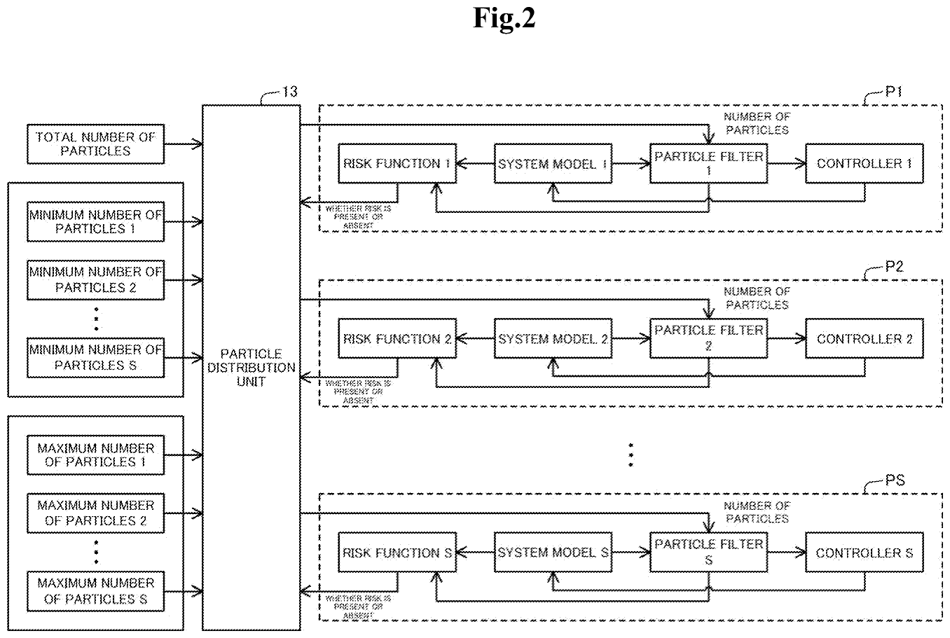

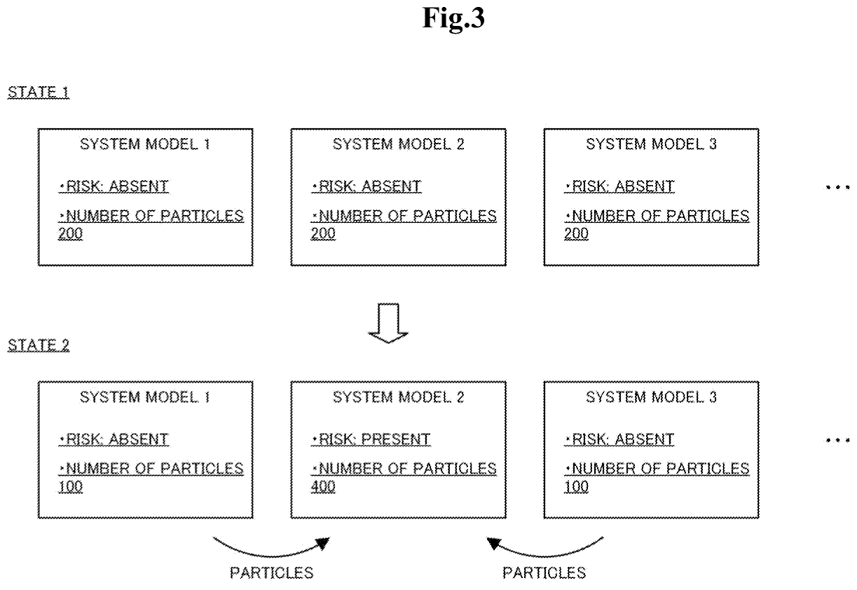

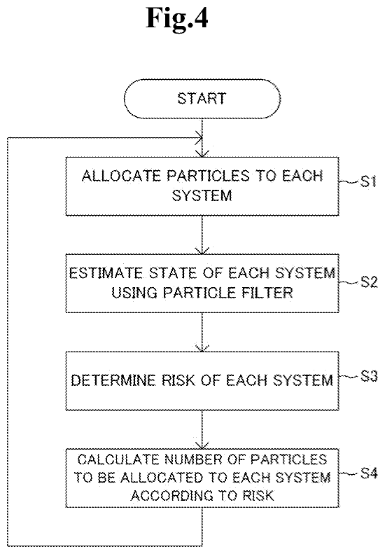

A first exemplary embodiment of the present disclosure will be described with reference to FIGS. 1 to 5. FIGS. 1 and 2 are diagrams for illustrating the configuration of an estimation system, and FIGS. 3 and 4 are diagrams for illustrating a processing operation of the estimation system.

### Configuration

An estimation system 10 according to the present exemplary embodiment is an information processing system that forms a plurality of particle filters for estimating states of a plurality of systems. For example, the estimation system 10 is used to estimate the state of a large-scale system including a large number of independent systems like a digital twin, i.e., the states of multiple systems by simulating them in parallel using the particle filters.

The estimation system 10 is configured of one or a plurality of information processing apparatus(es) each including an arithmetic device and a storage device. Then, the estimation system 10 includes a system estimation unit 11, a risk determination unit 12, and a particle allocation unit 13 as illustrated in FIG. 1. Each of the functions of the system estimation unit 11, the risk determination unit 12, and the particle allocation unit 13 can be realized through execution of a program for realizing each of the functions that is stored in the storage device by the arithmetic device. Further, the estimation system 10 includes a system model storage unit 16 and a particle information storage unit 17. The system model storage unit 16 and the particle information storage unit 17 are configured of the storage device. Hereinafter, each configuration will be described in detail.

The system model storage unit 16 stores therein models of a plurality of independent systems targeted for the estimation of the state. For example, the system model storage unit 16 stores therein each of a plurality of system models, like a system model 1, a system model 2, . . . One example of the number of system models is 100 or 1000, but this number is not limited. Each of the system models is configured to be able to estimate the state by conducting a simulation using the particle filter, as will be described below.

Now, one specific example of the system model is indicated by the following equation 1. The equation 1 expresses an example in a case where the system is a mobile robot, but the system model is not limited to the example that will be described below.
xₜ^{(s)}: a state variable (a position, a speed, or the like)
yₜ^{(s)}: an observed value (a sensor value (including noise))
ₜ^{(s)}: a control input (for example, a speed instruction)

xₜ^{(s)}˜p^{(s)}(xₜ^{(s)}|xₜ₋₁^{(s)}, uₜ₋₁^{(s)}: a probability model of state transition of a system (a motion equation)

xₜ^{(s)}˜q^{(s)}(yₜ^{(s)}|xₜ^{(s)}: a probability model of the observed value (a model of the sensor noise) [Equation 1]
s=1,2, . . ., S: a system number

The particle information storage unit 17 stores therein information regarding the number of particles allocated to each system model as will be described below, as information regarding particles used in the particle filter. For example, the particle information storage unit 17 stores therein the total number of particles allocatable to the system models, the minimum number of particles allocated to each system model, and the maximum number greater than this minimum number. The total number of particles is 10000, the minimum number of particles is 200, and the maximum number of particles is 500 as one example, but they are not limited to these numbers. Note that each of the minimum number and the maximum number of particles may be set to a different value according to a system model. For example, the minimum number and the maximum number may be set to 200 and 500, respectively, for the system model 1, and may be set to 300 and 600, respectively, for the system model 2.

Note that the reason for setting the total number of particles as described above is that, as the total number of particles increases, an information processing apparatus that performs the processing for estimating the state of the system should satisfy a higher arithmetic processing performance. Therefore, the total number of particles is set according to the hardware performance.

The system estimation unit 11 estimates the state of each system model by simulating it using the particles allocated to each system model. Now, FIG. 2 illustrates another exemplary configuration of the estimation system 10. As indicated by reference numerals P1 to PS in this drawing, the system estimation unit 11 sets particle filters 1 to S constituted by the particles allocated to the system models 1 to S, respectively, and also allocates controllers 1 to S to the system models 1 to S, respectively. Then, the controllers 1 to S estimate the states by simulating the respective states of the system models 1 to S using the particle filters 1 to S allocated to the system models 1 to S, respectively.

Now, a specific example of the estimation of the state based on the simulation using the particle filter with respect to each system model by the system estimation unit 11 is indicated by the following equation 2. In this equation, the system model indicated in the above-described equation 1 is used. Note that the processing content of the following particle filter is already known.

$$i = 1 , 2 , … , {N}_{t - 1}^{( s )} : \qquad [ Equation 2 ]$$

$$Make a calculation the same number$$

$$of times as the number of particles .$$

$${x}_{0 \vert 0}^{( s )} ( i ) \sim {p}_{0}^{( s )} : Set an initial particle .$$

$${x}_{t \vert t - 1}^{( s )} ( i ) \sim {p}^{( s )} ( {x}_{t \vert t - 1}^{( s )} ( i ) \vert {x}_{t - 1 \vert t - 1}^{( s )} ( i ) , {u}_{t - 1}^{( s )} ) :$$

$$Move ( estimate ) each particle .$$

$${w}_{t}^{( s )} ( i ) = {q}^{( s )} ( {y}_{t}^{( s )} \vert {x}_{t \vert t - 1} ( s ) ) : Calculate a likelihood of each particle .$$

$${W}_{t}^{( s )} ( i ) = {\sum }_{i = 1}^{{N}_{t - 1}^{( s )}} {w}_{t}^{( s )} ( i ) : Sum the likelihoods of all the particles .$$

$$Particles are sampled from {X}_{t \vert t - 1}^{( s )} = \{ {x}_{t \vert t - 1}^{( s )} ( 1 ) , … , \vert {x}_{t \vert t - 1}^{( s )} ( {N}_{t - 1}^{( s )} ) \} according to a probability {\tilde{w}}_{t}^{( s )} = \frac{{w}_{t}^{( s )}}{{W}_{t}^{( s )}} while being allowed to be extracted more than once , \\ and new particles {X}_{t \vert t - 1}^{( s )} = \{ {x}_{t \vert t}^{( s )} ( 1 ) , … , \vert {x}_{t \vert t - 1}^{( s )} ( {N}_{t}^{( s )} ) \} are created .$$

$$The sought estimated value is calculated as \\ an average of the new particles {\hat{x}}_{t}^{( s )} = \frac{1}{{N}_{f}^{( s )}} {\sum }_{i = 1}^{{N}_{t}^{( s )}} {x}_{t \vert t}^{( s )} ( i ) .$$

Then, as will be described below, the number of particles to be allocated to each system later is calculated according to the estimated value, and the system estimation unit 11 estimates the state by simulating each system again in the above-described manner while setting the calculated number of particles to each system. This means that the system estimation unit 11 repeats the above-described estimation of the state of each system while changing the number of allocated particles.

The risk determination unit 12 (a determination unit) determines a risk of the state of each system based on the state of each system. Now, the risk is defined to be whether the state of the system matches a preset risk state or a degree to which the state of the system matches a risk state based on a preset reference, and indicates, for example, a risk level or an uncertainty level of the state of the system based on a preset reference. In the present exemplary embodiment, the risk determination unit 12 is assumed to determine whether the risk is present or absent based on the value of the state of the system estimated from the simulation using the particle filter in the above-described manner. In other words, the risk determination unit 12 is assumed to determine that the risk is present if the state variable (for example, the speed) indicating the state of the system is greater than a threshold value or an error between the estimated value and the observed value is greater than a threshold value, and otherwise determine that the risk is absent as one example. At this time, the risk determination unit 12 prepares risk determination functions 1 to S for the individual system models 1 to S, respectively, as illustrated in FIG. 2, and determines whether the risk is present or absent by inputting the states of the systems to these risk determination functions 1 to S, respectively.

For example, the determined risk is assumed to be expressed as indicated by the following equation 3.

$${R}^{( s )} ( {x}_{t} , {y}_{t} , {u}_{t} ) = \{ \begin{matrix}1 & ( the risk is present ) \\ 0 & ( the risk is absent )\end{matrix} \qquad [ Equation 3 ]$$

However, the risk determination unit 12 is not necessarily limited to determining the risk based on the state of each system as whether the risk is present or absent. For example, the risk determination unit 12 may determine the risk based on the state of each system as a numerical value indicating the degree of being in the risk state. At this time, the risk determination unit 12 may express the degree of being in the risk state in the form of, for example, a numeral value capable of indicating one of a plurality of stages.

The particle allocation unit 13 (a calculation unit) calculates the number of particles to be allocated to each system based on the risk determined for each system in the above-described manner. At this time, the particle allocation unit 13 calculates the number of particles so as to allocate at least the minimum number of particles to a system determined not to have the risk and allocate the number of particles greater than the minimum number and equal to or smaller than the maximum number to a system determined to have the risk within such a range that the sum of the numbers of particles to be allocated to all the systems does not exceed the preset total number of particles.

More specifically, the particle allocation unit 13 calculates the number of particles to be allocated to each system as indicated by the following equation 5 when each parameter is set as indicated by the following equation 4.

### [Equation 4]

N: the total number of particles
Nₘᵢₙ^{(s)}: the minimum number of particles
N_{boost}^{(s)}: the maximum number of particles
[symbol] : a set of systems having the risk
[symbol] : a set of systems not having the risk

$$\begin{matrix}[ Equation 5 ] & \\ If {\sum }_{s ∈ ℋ} {N}_{boost}^{( s )} + {\sum }_{s ∈ ℒ} {N}_{min}^{( s )} \leq N , \\ {N}^{( s )} = \{ \begin{matrix}{N}_{boost}^{( s )} & ( s ∈ ℋ ) \\ \frac{N - {\sum }_{s ∈ ℋ} {N}_{boost}^{( s )}}{\vert ℒ \vert} & ( s ∈ ℒ )\end{matrix} & ( 1 )\end{matrix}$$

$$If {\sum }_{s ∈ ℋ} {N}_{boost}^{( s )} + {\sum }_{s ∈ ℒ} {N}_{min}^{( s )} \leq N , \\ {N}^{( s )} = \{ \begin{matrix}{N}_{boost}^{( s )} & ( s ∈ ℋ ) \\ \frac{N - {\sum }_{s ∈ ℋ} {N}_{boost}^{( s )}}{\vert ℒ \vert} & ( s ∈ ℒ )\end{matrix} \qquad ( 2 )$$

Note that, if the minimum number and the maximum number of particles are set for each system as described above, the particle allocation unit 13 calculates the number of particles to be allocated in the above-described manner using these values.

Further, if the risk is not determined as whether the risk is present or absent unlike the above description and is determined in a stepwise manner as, for example, the degree of risk, the particle allocation unit 13 calculates the number of particles to be allocated to each system according to this degree of risk. For example, the particle allocation unit 13 calculates the number of particles so as to allocate a larger number of particles to a system corresponding to a higher degree of risk. In other words, the particle allocation unit 13 calculates the number of particles so as to allocate a larger number of particles to a system corresponding to a high degree of risk than a system corresponding to a low degree of risk. However, even in this case, the particle allocation unit 13 calculates the number of particles so as to keep it within such a range that the sum of the numbers of particles to be allocated to all the systems does not exceed the total number and also allocate at least the minimum number of particles to all the systems.

Then, the particle allocation unit 13 notifies the system estimation unit 11 of the number of particles calculated with respect to each system. Due to that, the system estimation unit 11 repeatedly sets the calculated number of particles to each system and estimates the state of each system as described above.

Now, FIG. 3 illustrates one example of the allocation of the number of particles by the above-described estimation unit 10. First, suppose that, when each of the system models 1 to 3 is in a “state 1”, the risk is “absent” and the number of particles is “200” for any of them. Then, when each of the system models 1 to 3 is estimated to be in a “state 2”, the number of particles “100” is allocated to the system models 1 and 3 the risk of which is “absent”, and the number of particles “400” is allocated to the system model 2 the risk of which is “present”. In this regard, assume that the number of particles “100” is equal to or greater than the minimum number and the number of particles “400” is equal to or smaller than the maximum number, and, further, the sum of the numbers of particles allocated to all the systems does not exceed the total number.

In this manner, in the estimation system 10 according to the present exemplary embodiment, a larger number of particles are allocated to a system having the risk and the state thereof is estimated subsequently. Therefore, an accurate estimation can be achieved using a larger number of particles with respect to a system having the risk. On the other hand, the minimum number of particles are allocated to a system not having the risk and the state thereof is estimated subsequently. Therefore, the required minimum estimation can continue even with respect to a system not having the risk, and therefore a stable and accurate estimation can be maintained. Then, at this time, particles more than the preset total number of particles are not allocated, and therefore the estimation processing can continue using only the calculation resources prepared in advance.

### Operation

Next, an operation of the above-described estimation system 10 will be described.

First, the estimation system 10 allocates the same number of particles as a set initial value to each system (step S1). Then, the estimation system 10 estimates the state using the particle filter including the allocated number of particles with respect to each system (step S2).

Subsequently, the estimation system 10 determines the risk of each system based on the estimated state of each system (step S3). For example, the estimation system 10 determines whether the risk is present or absent based on the state of each system. Then, the estimation system 10 calculates the number of particles to be allocated based on the presence or absence of the risk of each system (step S4). At this time, the estimation system 10 calculates the number of particles so as to allocate at least the minimum number of particles to a system determined not to have the risk and allocate the number of particles greater than the minimum number and equal to or smaller than the maximum number to a system determined to have the risk within such a range that the sum of the numbers of particles to be allocated to all the systems does not exceed the preset total number of particles.

Then, the estimation system 10 repeatedly allocates the same number of particles as the number calculated with respect to each system to each system (step S1) and estimates the state of each system (step S2).

In this manner, the present configuration causes the estimation system 10 to allocate a larger number of particles to a system having the risk and allocate the minimum number of particles even to a system not having the risk, and estimate the state of each system after that. Therefore, the estimation system 10 can further accurately estimate the state using a large number of particles with respect to a system having the risk and continue the estimation even with respect to a system not having the risk, thereby achieving a stable and accurate estimation.

### EXAMPLE

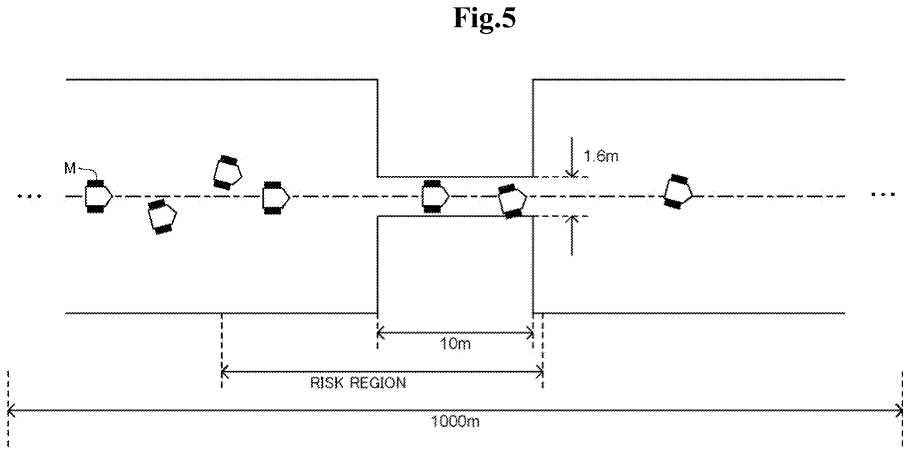

Next, an example in which the above-described estimation system 10 is applied to a specific system will be described with reference to FIG. 5.

FIG. 5 illustrates systems targeted for the estimation of the state using the particle filters. In this example, suppose that the systems targeted for the estimation are a plurality of mobile robots M, and the states of this plurality of mobile robots M are estimated in parallel using the particle filters and the running thereof is controlled according to the estimation result. More specifically, in this example, suppose that, with the aim of controlling 1000 mobile robots M in such a manner that they run on a running line indicated by a broken line at the center in a movement path extending horizontally in FIG. 5, coordinates in the movement path, i.e., coordinates (x, y, θ) constituted by a position (x, y) and an angle (θ) indicating a traveling direction are estimated as the state of the mobile robot M at this time. Then, suppose that, for example, the respective speeds of the left wheel and the right wheel are controlled as the control on the mobile robot M.

In addition thereto, suppose that, in the example, a “bridge” 10 m in length is set up in the middle of the movement path 1000 m in total length as illustrated in FIG. 5. Note that the width of the “bridge” is set to 1.6 m, which is narrower than other portions. Then, as illustrated in FIG. 5, a range within 20 m in front of the “bridge” and a range within 1 m behind the “bridge are set as a risk region, which causes the risk to be determined to be present if the estimated coordinates of the mobile robot M are located in the risk region.

Employing the estimation system 10 according to the present disclosure in the above-described situation allows the coordinates corresponding to the state of each of the mobile robots M to be estimated using the particle filter, the risk to be determined based on these coordinates, and, further, the number of particles to be calculated for being allocated to each of the mobile robots M. According thereto, the mobile robot M located in the risk region near the “bridge” is determined to have the risk, thereby resulting in receiving the allocation of a larger number of particles. On the other hand, the mobile robot M located outside the risk region away from the “bridge” is determined not to have the risk, and results in receiving the allocation of at least the minimum number of particles. Therefore, for the mobile robot M determined to have the risk, the coordinates are estimated using a larger number of particles, and therefore can be estimated further accurately, allowing the mobile robot M to be controlled so as not to fall from the bridge. On the other hand, for the mobile robot M determined not to have the risk, the coordinates are estimated using the minimum number of particles, thereby also allowing this mobile robot M to be controlled so as to run within the movement path.

Now, in the above-described example, the minimum number and the maximum number of particles to be allocated are set to 200 and 3000, respectively. Then, the acquired result is that, when the running of the 1000 mobile robots is controlled while the coordinates thereof are estimated simultaneously, 99% of the mobile robots do not fall from the “bridge”. On the other hand, the acquired result is that, when the running of the mobile robots is controlled while the coordinates thereof are estimated with a constant number of particles, 300 particles allocated to each of the mobile robots M, unlike the estimation system 10 according to the present disclosure, 88.1% of the mobile robots do not fall from the “bridge”. In this manner, the present example reveals that the estimation system 10 according to the present disclosure improves the stability and the accuracy when estimating the state.

### Second Exemplary Embodiment

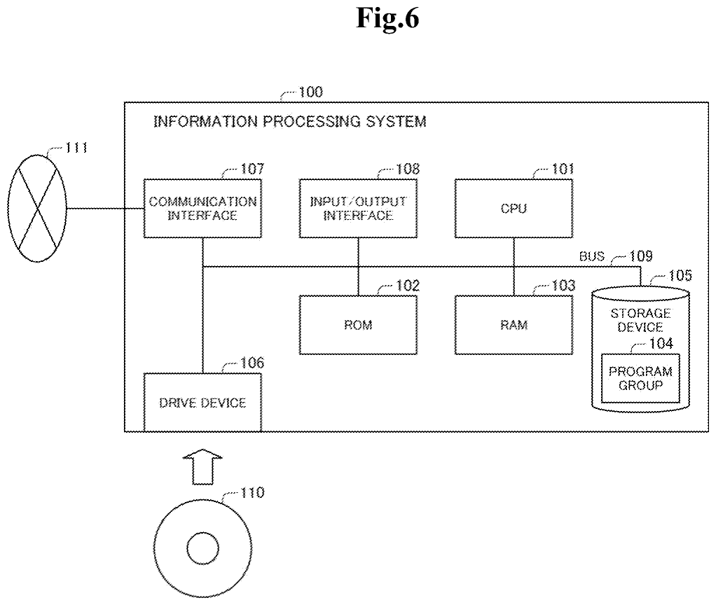

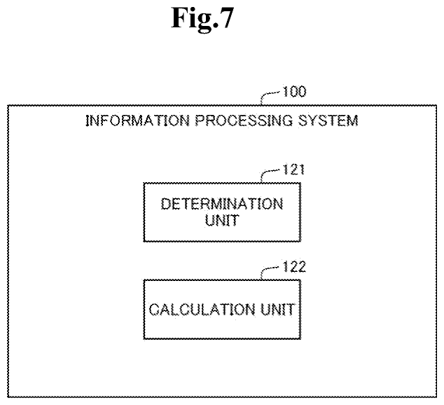

Next, a second exemplary embodiment of the present disclosure will be described with reference to FIGS. 6 and 7. FIGS. 6 and 7 are block diagrams illustrating the configuration of an information processing system according to the second exemplary embodiment. Note that the present exemplary embodiment indicates the outline of the configuration of the information processing system described in the above-described exemplary embodiment.

First, the hardware configuration of an information processing system 100 according to the present exemplary embodiment will be described with reference to FIG. 6. The information processing system 100 is configured of a typical information processing apparatus, and has the following hardware configuration as one example.
CPU (Central Processing Unit) 101 (arithmetic device)
ROM (Read Only Memory) 102 (storage device)
RAM (Random Access Memory) 103 (storage device)
Program group 104 that is loaded into the RAM 103
Storage device 105 storing therein the program group 104
Drive device 106 in charge of reading from and writing into a storage medium 110 outside the information processing apparatus
Communication interface 107 connected to a communication network 111 outside the information processing apparatus
Input/output interface 108 that inputs and outputs data
Bus 109 connecting each constituent element

Note that FIG. 6 illustrates one example of the hardware configuration of an information processing apparatus that is the information processing system 100, and the hardware configuration of the information processing apparatus is not limited to the above-described example. For example, the information processing apparatus may be configured of a part of the above-described configuration, such as a configuration not including the drive device 106. Further, the information processing apparatus can use a GPU (Graphic Processing Unit), a DSP (Digital Signal Processor), an MPU (Micro Processing Unit), an FPU (Floating point number Processing Unit), a PPU (Physics Processing Unit), a TPU (Tensor Processing Unit), a quantum processor, or a micro controller, or a combination thereof, instead of the above-described CPU.

Then, the information processing system 100 can construct and include a determination unit 121 and a calculation unit 122 illustrated in FIG. 7 through acquisition of the program group 104 by the CPU 101 and execution of the program group 104 by this CPU 101. Note that the program group 104 is, for example, stored in the storage device 105 or the ROM 102 in advance, and is loaded into the RAM 103 and executed by the CPU 101 as needed. Alternatively, the program group 104 may be supplied to the CPU 101 via the communication network 111, or may be stored in the storage medium 110 in advance and be read out and supplied to the CPU 101 by the drive device 106. However, the above-described determination unit 121 and calculation unit 122 may be constructed by electronic circuits designed specifically for realizing these units.

The above-described information processing system 100 is an information processing system that forms a plurality of particle filters for estimating states of a plurality of systems.

The above-described determination unit 121 determines a risk of the state of each system based on the state of each system. For example, the determination unit determines the presence or absence of the risk indicating whether the state of the system is in a preset risk state.

The above-described calculation unit 122 calculates the number of particles to be allocated to each system based on the risk and also calculates the number of particles so as to allocate at least a preset minimum number of particles to all the systems. For example, the calculation unit calculates the number of particles so as to allocate a larger number of particles to a system the risk of which is high than a system the risk of which is low.

By being configured in this manner, the present disclosure leads to the allocation of at least the minimum number of particles to all the systems based on the risk determined from the state of the system. Therefore, the estimation of the system can continue with respect to all the systems, and a stable and accurate estimation can be maintained.

Note that the above-described program can be stored using various types of non-transitory computer readable media and supplied to a computer. The non-transitory computer readable media include various types of tangible storage media. Examples of the non-transitory computer readable media include a magnetic recording medium (for example, a flexible disk, a magnetic tape, and a hard disk drive), a magneto-optical recording medium (for example, a magneto-optical disk), a CD-ROM (Read Only Memory), a CD-R, a CD-R/W, and a semiconductor memory (for example, a mask ROM, a PROM (Programmable ROM), an EPROM (Erasable PROM), a flash ROM, and a RAM (Random Access Memory)). Alternatively, the program may also be supplied to the computer via various types of transitory computer readable media. Examples of the transitory computer readable media include electric signals, optical signals, and electromagnetic waves. The transitory computer readable media can supply the program to the computer via a wired communication channel such as an electric wire and an optical fiber, or a wireless communication channel.

Having described the present disclosure with reference to the above-described exemplary embodiments and the like, the present disclosure is not limited to the above-described exemplary embodiments. The form and details of the present disclosure can be changed within the scope of the present disclosure in various manners that can be understood by those skilled in the art. Further, at least one or more function(s) among the functions of the above-described determination unit 121 and calculation unit 122 may be executed by an information processing apparatus set up at any location in a network and connected therefrom, i.e., may be executed by so-called cloud computing.

### Supplementary Notes

A part or whole of the above-described exemplary embodiments can also be described as, but not limited to, the following supplementary notes. Hereinafter, the outlines of the configurations of an information processing apparatus, an information processing method, and a program according to the present disclosure will be described. However, the present disclosure is not limited to the following configurations.

### (Supplementary Note 1)

An information processing system configured to form a plurality of particle filters for estimating states of a plurality of systems, the information processing system comprising:
a determination unit configured to determine a risk of the state of each of the systems based on the state of each of the systems; and
a calculation unit configured to calculate the number of particles to be allocated to each of the systems based on the risk and also calculate the number of particles so as to allocate at least a preset minimum number of particles to all the systems.

### (Supplementary Note 2)

The information processing system according to supplementary note 1, wherein
the calculation unit calculates the number of particles so as to allocate a larger number of the particles to the system the risk of which is high than the system the risk of which is low.

### (Supplementary Note 3)

The information processing system according to supplementary note 2, wherein
the determination unit determines whether the risk is present or absent; and
the calculation unit calculates the number of particles so as to allocate a larger number of the particles to the system having the risk than the system not having the risk.

### (Supplementary Note 4)

The information processing system according to supplementary note 3, wherein
the calculation unit calculates the number of particles so as to allocate at least the minimum number of the particles to the system not having the risk and allocate the particles more than the minimum number to the system having the risk.

### (Supplementary Note 5)

The information processing system according to supplementary note 4, wherein
the minimum number, a maximum number greater than the minimum number, and a total number of the particles that can be allocated are set, and
the calculation unit calculates the number of particles so as to allocate the particles less than the maximum number and equal to or more than the minimum number to the system not having the risk and allocate the particles more than the minimum number and equal to or less than the maximum number to the system having the risk while keeping a sum of the numbers of particles to be allocated to all the systems from exceeding the total number.

### (Supplementary Note 6)

The information processing system according to supplementary note 5, wherein
the minimum number and the maximum number are each set to a different value according to the system.

### (Supplementary Note 7)

An information processing method for forming a plurality of particle filters for estimating states of a plurality of systems, the information processing method comprising:

determining a risk of the state of each of the systems based on the state of each of the systems; and
calculating the number of particles to be allocated to each of the systems based on the risk and also calculating the number of particles so as to allocate at least a preset minimum number of particles to all the systems.

### (Supplementary Note 8)

The information processing method according to supplementary note 7, comprising:
calculating the number of particles so as to allocate a larger number of the particles to the system the risk of which is high than the system the risk of which is low.

### (Supplementary Note 9)

The information processing method according to supplementary note 8, comprising:
determining whether the risk is present or absent; and
calculating the number of particles so as to allocate a larger number of the particles to the system having the risk than the system not having the risk.

### (Supplementary Note 10)

The information processing method according to supplementary note 9, comprising:
calculating the number of particles so as to allocate at least the minimum number of the particles to the system not having the risk and allocate the particles more than the minimum number to the system having the risk.

### (Supplementary Note 11)

The information processing method according to supplementary note 10, wherein
the minimum number, a maximum number greater than the minimum number, and a total number of the particles that can be allocated are set,
the information processing method comprising:
calculating the number of particles so as to allocate the particles less than the maximum number and equal to or more than the minimum number to the system not having the risk and allocate the particles more than the minimum number and equal to or less than the maximum number to the system having the risk while keeping a sum of the numbers of particles to be allocated to all the systems from exceeding the total number.

### (Supplementary Note 12)

A program comprising instructions for causing a computer to execute processing for forming a plurality of particle filters for estimating states of a plurality of systems, the processing comprising:

determining a risk of the state of each of the systems based on the state of each of the systems; and
calculating the number of particles to be allocated to each of the systems based on the risk and also calculating the number of particles so as to allocate at least a preset minimum number of particles to all the systems.

### REFERENCE SIGNS LIST

10 estimation system
11 system estimation unit
12 risk determination unit
13 particle allocation unit
16 system model storage unit
17 particle information storage unit
100 information processing system
101 CPU
102 ROM
103 RAM
104 program group
105 storage device
106 drive device
107 communication interface
108 input/output interface
109 bus
110 storage medium
111 communication network
121 determination unit
122 calculation unit

1. An information processing system configured to form a plurality of particle filters for estimating states of a plurality of systems, the information processing system comprising:
at least one memory configured to store processing instructions; and
at least one processor configured to execute the processing instructions to:
determine a risk of the state of each of the systems based on the state of each of the systems; and
calculate the number of particles to be allocated to each of the systems based on the risk and also calculate the number of particles so as to allocate at least a preset minimum number of particles to all the systems.

2. The information processing system according to claim 1, wherein
the at least one processor configured to execute the processing instructions to:
calculate the number of particles so as to allocate a larger number of the particles to the system the risk of which is high than the system the risk of which is low.

3. The information processing system according to claim 2, wherein
the at least one processor configured to execute the processing instructions to:
determine whether the risk is present or absent; and
calculate the number of particles so as to allocate a larger number of the particles to the system having the risk than the system not having the risk.

4. The information processing system according to claim 3, wherein
the at least one processor configured to execute the processing instructions to:
calculate the number of particles so as to allocate at least the minimum number of the particles to the system not having the risk and allocate the particles more than the minimum number to the system having the risk.

5. The information processing system according to claim 4, wherein
the minimum number, a maximum number greater than the minimum number, and a total number of the particles that can be allocated are set, and
the at least one processor configured to execute the processing instructions to:
calculate the number of particles so as to allocate the particles less than the maximum number and equal to or more than the minimum number to the system not having the risk and allocate the particles more than the minimum number and equal to or less than the maximum number to the system having the risk while keeping a sum of the numbers of particles to be allocated to all the systems from exceeding the total number.

6. The information processing system according to claim 5, wherein
the minimum number and the maximum number are each set to a different value according to the system.

7. An information processing method for forming a plurality of particle filters for estimating states of a plurality of systems, the information processing method comprising:
determining a risk of the state of each of the systems based on the state of each of the systems; and
calculating the number of particles to be allocated to each of the systems based on the risk and also calculating the number of particles so as to allocate at least a preset minimum number of particles to all the systems.

8. The information processing method according to claim 7, comprising:
calculating the number of particles so as to allocate a larger number of the particles to the system the risk of which is high than the system the risk of which is low.

9. The information processing method according to claim 8, comprising:
determining whether the risk is present or absent; and
calculating the number of particles so as to allocate a larger number of the particles to the system having the risk than the system not having the risk.

10. The information processing method according to claim 9, comprising:
calculating the number of particles so as to allocate at least the minimum number of the particles to the system not having the risk and allocate the particles more than the minimum number to the system having the risk.

11. The information processing method according to claim 10, wherein
the minimum number, a maximum number greater than the minimum number, and a total number of the particles that can be allocated are set,
the information processing method comprising:
calculating the number of particles so as to allocate the particles less than the maximum number and equal to or more than the minimum number to the system not having the risk and allocate the particles more than the minimum number and equal to or less than the maximum number to the system having the risk while keeping a sum of the numbers of particles to be allocated to all the systems from exceeding the total number.

12. A non-transitory computer-readable storage medium storing therein a program comprising instructions for causing a computer to execute processing for forming a plurality of particle filters for estimating states of a plurality of systems, the processing comprising:
determining a risk of the state of each of the systems based on the state of each of the systems; and
calculating the number of particles to be allocated to each of the systems based on the risk and also calculating the number of particles so as to allocate at least a preset minimum number of particles to all the systems.
